(19) United States
(12) Patent Application Publication
(10) Pub. No.: US 2009/0040857 A1
(43) Pub. Date: Feb. 12, 2009

(54) INTEGRATED CIRCUIT INCLUDING DECOUPLING CAPACITORS THAT CAN BE DISABLED

(76) Inventors: Grant McNeil, Williston, VT (US); Ernst Stahl, Essex Junction, VT (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/835,675

(22) Filed: Aug. 8, 2007

(51) Int. Cl. G11C 5/14

(52) U.S. Cl. 365/226

(57) ABSTRACT

An integrated circuit includes a decoupling capacitor configured to be enabled in response to the decoupling capacitor not increasing a standby current of the integrated circuit and disabled in response to the decoupling capacitor increasing the standby current of the integrated circuit.

### BACKGROUND

Many mobile devices require dynamic random access memories (DRAMs) with extremely low standby power specifications to conserve battery power. For example, one type of DRAM designed for mobile devices has a specified standby current of about 100 μA. The suppression of leakage current is typically more difficult in DRAMs designed for mobile use than in standard or commodity DRAMs since even a small leakage current has a large contribution to the overall standby current.

On chip decoupling capacitors, which are typically deep trench capacitors, are used in commodity and mobile DRAM products. The decoupling capacitors are typically placed along the chip edge or memory array edge in groups of approximately 32 small capacitor arrays. Each capacitor array, depending on its size, provides a capacitance for example on the order of 887 pf (e.g., an array of 30 μm by 100 μm or approximately 35,490 deep trench capacitors at a cell capacitance of approximately 25 fF). If a defect occurs in a decoupling capacitor in the upper layers (e.g., bit line contact to gate contact (CB-GC) short), since the upper layers are all connected to the same potential (i.e., ground) the defect does not affect the leakage current. If, however, the trench of a decoupling capacitor leaks or shorts to the plate, then up to approximately 300 μA leakage current may result depending upon the affected voltage network and the leakage/strap resistance.

For commodity DRAM products, 300 μA leakage current is typically not a problem as long as the affected voltage network can support the current and provided that the standby current specification for the commodity DRAM is not violated. The standby current specification for commodity DRAM is typically in the 2-5 mA range. For mobile DRAM products where the standby current specification may be 100 μA, however, the standby current is more critical and 300 μA leakage current may result in yield loss. Typically, mobile DRAM products use improved fabrication processes to limit defective decoupling capacitors. In addition, mobile DRAM products are typically screened based on standby current and products that do not meet the standby current specifications are excluded, resulting in yield loss.

For these and other reasons, there is a need for the present invention.

### SUMMARY

One embodiment provides an integrated circuit. The integrated circuit includes a decoupling capacitor configured to be enabled in response to the decoupling capacitor not increasing a standby current of the integrated circuit and disabled in response to the decoupling capacitor increasing the standby current of the integrated circuit.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of a system.

FIG. 2 is a schematic diagram illustrating one embodiment of decoupling capacitor circuits.

FIG. 3 is a diagram illustrating one embodiment of a decoupling capacitor circuit.

FIG. 4 illustrates one embodiment of a layout for a decoupling capacitor circuit.

FIG. 5 is a flow diagram illustrating one embodiment of a process for testing decoupling capacitors.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

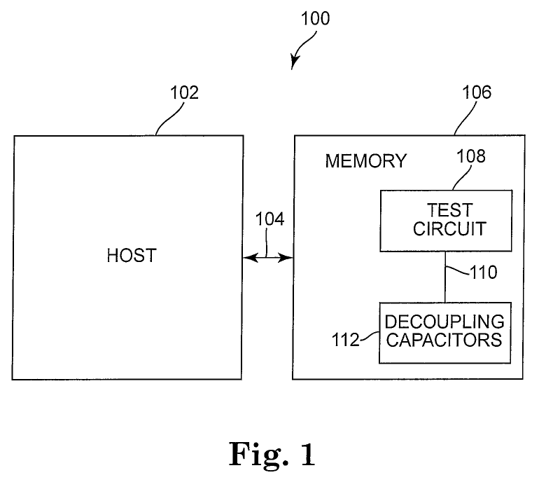

FIG. 1 is a block diagram illustrating one embodiment of a system 100. System 100 includes a host 102 and a memory 106. Host 102 is electrically coupled to memory 106 through memory communication path 104. Memory 106 includes a test circuit 108, decoupling capacitor circuits 112, and other memory circuits (not shown). Test circuit 108 is electrically coupled to decoupling capacitor circuits 112 through signal path 110. Host 102 reads data from memory 106 and writes data to memory 106 through memory communication path 104.

Test circuit 108 implements a test mode that identifies leaking capacitors within decoupling capacitor circuits 112 by switching in and out each decoupling capacitor and measuring the change in leakage current. By measuring the change in leakage current, the location of leaking decoupling capacitors is identified. The leaking decoupling capacitors are then isolated from the remaining circuit using fusing or other suitable technique. With the leaking decoupling capacitors isolated from the remaining circuit, the standby current of memory 106 is not increased. A few decoupling capacitors can be isolated from the remaining circuit without having a significant impact on the total decoupling or buffer capacitance.

In one embodiment, host 102 includes a computer (e.g., desktop, laptop, handheld), portable electronic device (e.g., cellular phone, personal digital assistant (PDA), MP3 player, video player), or any other suitable device that uses memory. Host 102 includes logic, firmware, and/or software for controlling the operation of memory 106. In one embodiment, host 102 includes a microcontroller, microprocessor, or other suitable device capable of passing a clock signal, address signals, command signals, and data signals to memory 106 though memory communication path 104. Host 102 passes the clock signal, address signals, command signals, and data signals to memory 106 through memory communication path 104 to read data from and write data to memory 106.

Memory 106 includes circuits for communicating with host 102 through memory communication path 104 and for reading and writing data in memory 106. Memory 106 includes a random access memory (RAM), such as a dynamic random access memory (DRAM), a synchronous dynamic random access memory (SDRAM), a double data rate synchronous dynamic random access memory (DDR-SDRAM), a low power SDRAM (e.g., MOBILE-RAM), or another suitable memory. Memory 106 responds to memory read requests from host 102 and passes the requested data to host 102. Memory 106 responds to write requests from host 102 and stores data in memory 106 passed from host 102.

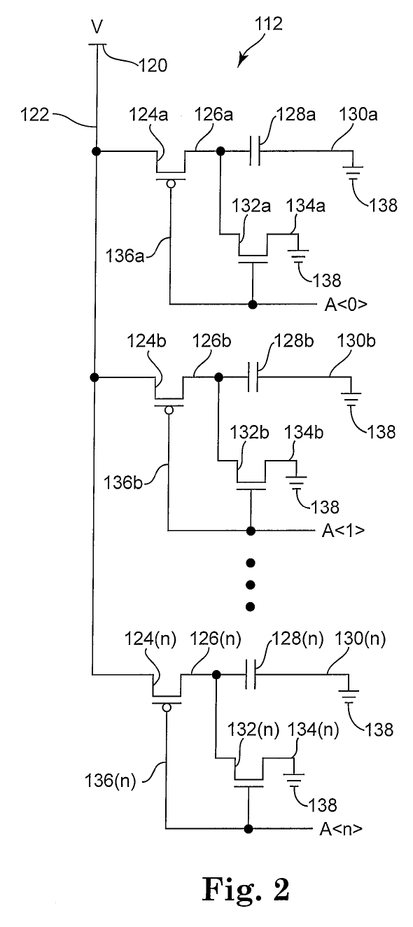

FIG. 2 is a schematic diagram illustrating one embodiment of decoupling capacitor circuits 112. Each decoupling capacitor circuit includes a transistor 124a-124(n), a transistor 132a-132(n), and a decoupling capacitor 128a-128(n), where “n” indicates any suitable number of decoupling capacitors, such as 32. One side of the source-drain path of each transistor 124a-124(n) is electrically coupled to a voltage source (V) 120 through signal path 122. The other side of the source-drain path of each transistor 124a-124(n) is electrically coupled to one side of decoupling capacitor 128a-128(n) and one side of the source-drain path of transistor 132a-132(n) through signal path 126a-126(n), respectively. The other side of each decoupling capacitor 128a-128(n) is electrically coupled to ground 138 through signal path 130a-130(n), respectively. The other side of each source-drain path of each transistor 132a-132(n) is electrically coupled to ground 138 through signal path 134a-134(n), respectively. The gate of each transistor 124a-124(n) and the gate of each transistor 132a-132(n) is electrically coupled to A<0>-A<n> select signal path 136a-136(n), respectively.

In one embodiment, transistors 124a-124(n) are p-channel metal-oxide-semiconductor field effect transistors (MOSFETs) and transistors 132a-132(n) are n-channel MOSFETs. In one embodiment, voltage source 120 is an internal voltage (Vᵢₙₜ), a bit line high voltage (V_{blh}), or other suitable voltage source of memory 106. In one embodiment, decoupling capacitors 128a-128(n) are arrays of deep trench capacitors, parallel plate capacitors, or other suitable capacitors.

In response to a logic low A<0> signal on signal path 136a, transistor 124a turns on (conducting) and transistor 132a turns off (not conducting) to enable decoupling capacitor 128a by charging decoupling capacitor 128a from power source 120. In response to a logic high A<0> signal on signal path 136a, transistor 124a turns off and transistor 132a turns on to disable decoupling capacitor 128a by shorting decoupling capacitor 128a to ground 138. With decoupling capacitor 128a shorted to ground 138, decoupling capacitor 128a is isolated from the rest of decoupling capacitor circuits 112. Decoupling capacitors 128b-128(n) are enabled and disabled similarly to decoupling capacitor 128a.

During a test mode, test circuit 108 applies a logic low A<0> signal on signal path 136a to enable decoupling capacitor 128a to measure the leakage current through decoupling capacitor 128a. If test circuit 108 determines that decoupling capacitor 128a is leaking current, test circuit 108 sets the A<0> signal on signal path 136a to logic high via fusing or other suitable technique to disable decoupling capacitor 128a during operation of memory 106. With decoupling capacitor 128a disabled, decoupling capacitor 128a does not contribute to the leakage current. With no contribution to the leakage current, the standby current of memory 106 is not increased.

If test circuit 108 determines that decoupling capacitor 128a is not leaking current, test circuit 108 sets the A<0> signal on signal path 136a to logic low via fusing or other suitable technique to enable decoupling capacitor 128a during operation of memory 106. With decoupling capacitor 128a enabled, decoupling capacitor 128a contributes to the decoupling or buffer capacitance of memory 106. Test circuit 108 repeats the test process for decoupling capacitors 128b-128(n) and other decoupling capacitors within memory 106 to determine if the decoupling capacitors are leaking current. If test circuit 108 determines that any of the decoupling capacitors 128b-128(n) are leaking current, test circuit 108 shorts the leaking decoupling capacitors to ground 138. In this way, decoupling capacitors 128a-128(n) that exhibit leakage current are disabled during operation of memory 106 such that the standby current of memory 106 is not increased. By testing and disabling defective decoupling capacitors such that the standby current of memory 106 is not increased, the defective decoupling capacitors do not result in yield loss.

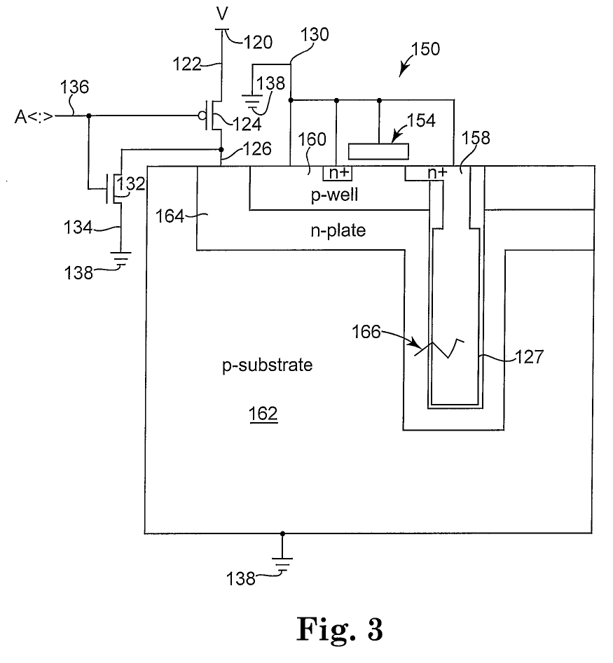

FIG. 3 is a diagram illustrating one embodiment of a decoupling capacitor circuit 150. Decoupling capacitor circuit 150 includes voltage source 120, a transistor 124, a transistor 132, a transistor 154, n+ region 158, deep trench capacitor 127, p-well 160, p-substrate 162, and n-plate 164. In one embodiment, deep trench capacitor 127 is one of the deep trench capacitors in an array of deep trench capacitors that provide a decoupling capacitor 128. In one embodiment, decoupling capacitor circuit 150 is fabricated in a similar manner as a one transistor, one capacitor, DRAM memory cell.

P-substrate 162 is electrically coupled to ground 138. The gate, source, and drain of transistor 154 are all electrically coupled to ground 138 through signal path 130 in decoupling capacitor circuit 150. One side of the source-drain path of transistor 154 electrically couples n+ region 158, which extends into deep trench capacitor 127, to ground 138. Defects in the upper area of n+ region 158 or transistor 154 do not affect the leakage current since these areas are coupled to ground 138. Defects in the lower area, such as leakage current through node dielectric as indicated at 166, however, do affect the leakage current since n-plate 164 is electrically coupled to voltage source 120.

In this case, where test circuit 108 detects leakage current 166, a logic high A<i> signal is provided on signal path 136 to short n-plate 164 to ground 138 through transistor 132 thereby disabling or deactivating decoupling capacitor 127. If test circuit 108 does not detect any leakage current, a logic low A<i> signal is provided on signal path 136 to charge n-plate 164 to voltage source 120 through transistor 124 thereby enabling or activating decoupling capacitor 127.

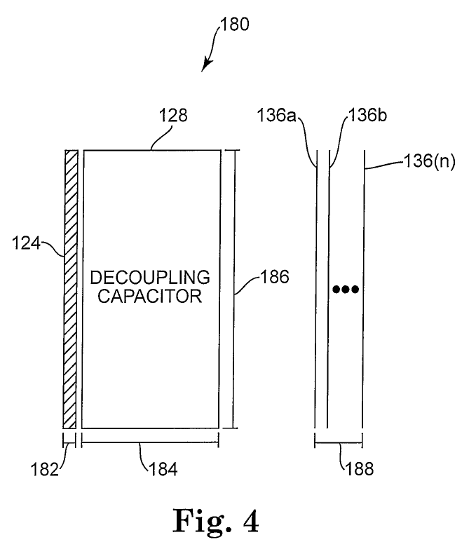

FIG. 4 illustrates one embodiment of a layout 180 for a decoupling capacitor circuit. In one embodiment, decoupling capacitor 128 has a width of 30 μm as indicated at 184 and a length of 100 μm as indicated at 186. Transistor 124 has a layout area width of 4 μm as indicated at 182. Transistor 124 is positioned adjacent the long side of decoupling capacitor 128. In one embodiment, where there are 32 decoupling capacitors 128, selection lines 136a-136(n) have a total width of approximately 13 μm as indicated at 188 at a line width of 0.2 μm and a line spacing of 0.2 μm. In other embodiments, other dimensions are possible as long as transistor 124 is as close as possible to decoupling capacitor 128.

In one embodiment, there are 32 individual decoupling capacitors 128. In one embodiment, each 30 μm by 100 μm decoupling capacitor 128 includes an array of 35,490 deep trench capacitors. Each deep trench capacitor has a capacitance of approximately 25 fF. Therefore, the total capacitance is approximately 887 pf for each decoupling capacitor 128. To individually activate or deactivate 32 decoupling capacitors 128, five bits are used for decoding. Each bit is set via the test mode of test circuit 108 and is fuseable. The 32 additional selection lines 136a-136(n) for enabling or disabling decoupling capacitors 128 may affect chip size and layout.

The size of transistors 124 are selected to be large enough to keep the channel resistance low and to guarantee a low time constant of decoupling capacitors 128. For example, with an 887 pf capacitor and to keep the time constant to approximately 2 ns, the additional resistance R allowed is R=2 ns/887 pf, which gives approximately 2Ω. To achieve a 2Ω channel resistance, the channel width of transistor 124 has to be about 800 μm. Transistor 124 is positioned adjacent the long edge of decoupling capacitor 128.

In one embodiment, to reduce the number of selection lines, pairs or groups of decoupling capacitor arrays are disabled together instead of enabling or disabling a single decoupling capacitor array while still only removing a small fraction of the overall decoupling or buffer capacitance. The pairs or groups of decoupling capacitors should be disabled evenly within the quad or banks of memory 106 such that functionality is not affected.

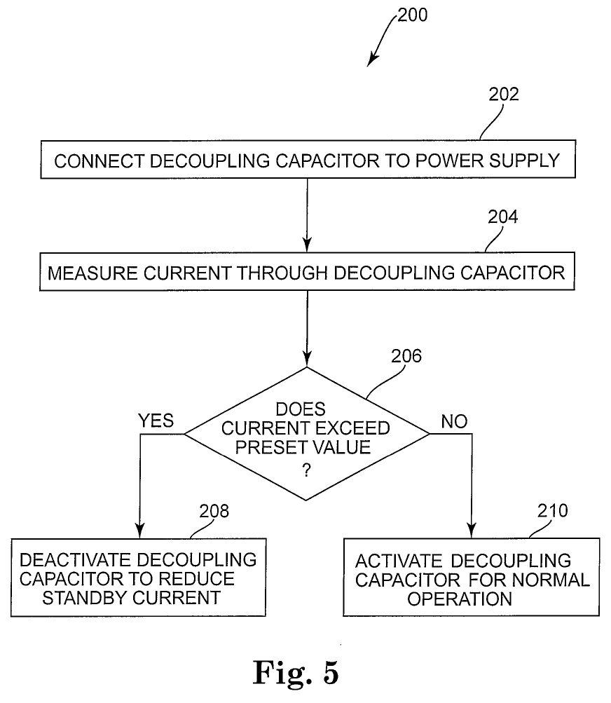

FIG. 5 is a flow diagram illustrating one embodiment of a process 200 for testing decoupling capacitors 128a-128(n). At 202, test circuit 108 is coupled to a first decoupling capacitor 128 and couples the decoupling capacitor to power source 120 through transistor 124. At 204, test circuit 108 measures the current through the decoupling capacitor to check for leakage current.

At 206, test circuit 108 determines whether the leakage current exceeds a predetermined value. If the leakage current exceeds the predetermined value, then at 208 test circuit 108 deactivates the decoupling capacitor to reduce the standby current by shorting the decoupling capacitor to ground 138 through transistor 132. If the leakage current does not exceed the predetermined value, then at 210 test circuit 108 activates the decoupling capacitor for normal operation by coupling the decoupling capacitor to power source 120 through transistor 124. In one embodiment, fusing is used to activate or deactivate each decoupling capacitor. Process 200 is repeated for each decoupling capacitor 128a-128(n) within memory 106.

Embodiments of the present invention provide decoupling capacitors that can be enabled or disabled based on whether the decoupling capacitors increase the leakage current of the memory device and thereby the standby current of the memory device. If a decoupling capacitor is found to increase the leakage current of the memory device, the decoupling capacitor is isolated from the remaining decoupling capacitors to reduce the standby current and improve the memory device yield. If the decoupling capacitor is found not to increase the leakage current of the memory device, the decoupling capacitor remains active to provide decoupling or buffer capacitance for the memory device.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
a decoupling capacitor configured to be enabled in response to the decoupling capacitor not increasing a standby current of the integrated circuit and disabled in response to the decoupling capacitor increasing the standby current of the integrated circuit.

2. The integrated circuit of claim 1, further comprising:
a test circuit configured to enable the decoupling capacitor in response to the test circuit determining that the decoupling capacitor does not increase a leakage current of the integrated circuit and disable the decoupling capacitor in response to the test circuit determining that the decoupling capacitor increases the leakage current of the integrated circuit.

3. The integrated circuit of claim 2, further comprising:
a power source;
a first transistor configured to selectively electrically couple the power source to the decoupling capacitor; and
a second transistor configured to selectively electrically couple the decoupling capacitor to ground,
wherein the test circuit is configured to enable the decoupling capacitor by turning on the first transistor and turning off the second transistor and to disable the decoupling capacitor by turning off the first transistor and turning on the second transistor.

4. The integrated circuit of claim 3, wherein the first transistor comprises a p-channel metal-oxide-semiconductor field effect transistor, and wherein the second transistor comprises an n-channel metal-oxide-semiconductor field effect transistor.

5. The integrated circuit of claim 1, wherein the decoupling capacitor comprises an array of deep trench capacitors.

6. The integrated circuit of claim 1, wherein the integrated circuit comprises a dynamic random access memory.

7. A system comprising:
a host; and
a memory communicatively coupled to the host, the memory comprising:
a decoupling capacitor; and
a test circuit configured to enable the decoupling capacitor in response to the decoupling capacitor not exhibiting leakage current and disable the decoupling capacitor in response to the decoupling capacitor exhibiting leakage current.

8. The system of claim 7, wherein the memory further comprises:
a power source;
a first transistor configured to selectively electrically couple the power source to the decoupling capacitor; and
a second transistor configured to selectively electrically couple the decoupling capacitor to ground,
wherein the test circuit is configured to enable the decoupling capacitor by turning on the first transistor and turning off the second transistor and to disable the decoupling capacitor by turning off the first transistor and turning on the second transistor.

9. The system of claim 7, wherein the host comprises a portable electronic device.

10. The system of claim 7, wherein the memory comprises a dynamic random access memory.

11. The system of claim 7, wherein the decoupling capacitor comprises an array of deep trench capacitors.

12. A circuit comprising:
a decoupling capacitor;
means for testing the decoupling capacitor for leakage current;
means for activating the decoupling capacitor in response to the decoupling capacitor having leakage current less than a predetermined value; and
means for deactivating the decoupling capacitor in response to the decoupling capacitor having leakage current greater than the predetermined value.

13. The circuit of claim 12, wherein the means for activating the decoupling capacitor comprises means for electrically coupling the decoupling capacitor to a power source, and wherein the means for deactivating the decoupling capacitor comprises means for electrically coupling the decoupling capacitor to ground.

14. The circuit of claim 12, wherein the decoupling capacitor comprises a parallel plate capacitor.

15. The circuit of claim 12, wherein the decoupling capacitor comprises an array of deep trench capacitors.

16. A method for operating an integrated circuit, the method comprising:
testing a decoupling capacitor for leakage current; and
activating the decoupling capacitor in response to the decoupling capacitor having leakage current less than a predetermined value and deactivating the decoupling capacitor in response to the decoupling capacitor having leakage current greater than the predetermined value.

17. The method of claim 16, wherein testing the decoupling capacitor comprises electrically coupling the decoupling capacitor to a power source and measuring a current through the decoupling capacitor.

18. The method of claim 16, wherein testing the decoupling capacitor comprises testing a decoupling capacitor comprising an array of deep trench capacitors.

19. The method of claim 16, wherein activating the decoupling capacitor comprises turning on a transistor to electrically couple the decoupling capacitor to a power supply.

20. The method of claim 16, wherein deactivating the decoupling capacitor comprises turning on a transistor to electrically couple the decoupling capacitor to ground.

21. A method for reducing standby current in a memory, the method comprising:
providing a plurality of decoupling capacitors;
testing each of the decoupling capacitors for leakage current;
enabling decoupling capacitors having a leakage current less than a predetermined value; and
disabling decoupling capacitors having a leakage current greater than the predetermined value.

22. The method of claim 21, wherein testing each decoupling capacitor comprises electrically coupling each decoupling capacitor to a power source and measuring a current through the decoupling capacitor.

23. The method of claim 21, wherein providing the plurality of decoupling capacitors comprises providing a plurality of arrays of deep trench capacitors.

24. The method of claim 21, wherein disabling decoupling capacitors comprises electrically coupling the decoupling capacitors to ground.

25. The method of claim 21, wherein enabling decoupling capacitors comprises electrically coupling the decoupling capacitors to a power supply.

26. A memory comprising:
a memory array;
decoupling capacitors along an edge of the memory array; and
a test circuit configured to enable each decoupling capacitor in response to determining that a decoupling capacitor does not increase a leakage current of the memory and disable each decoupling capacitor in response to determining that a decoupling capacitor increases the leakage current of the memory.
